(19) United States
(12) Patent Application Publication
(10) Pub. No.: US 2011/0040578 A1
(43) Pub. Date: Feb. 17, 2011

(54) Device, system and method of displaying and improving the access to disclosed medical data

(76) Inventor: James T. Ramsey, Norfolk, VA (US)

Correspondence Address: Welsh Flaxman & Gitler LLC, Suite 100, 2000 Duke Street, Alexandria, VA, 22314, US

(21) Appl. No.: 12/805,638

(22) Filed: Aug. 11, 2010

Related U.S. Application Data
(60) Provisional application No. 61/273,995, filed on Aug. 12, 2009.
(60) Provisional application No. 61/254,622, filed on Oct. 23, 2009.
(60) Provisional application No. 61/254,719, filed on Oct. 25, 2009.
(60) Provisional application No. 61/344,288, filed on Jun. 23, 2010.

(51) Int. Cl. G06Q 50/00; G06Q 10/00; G06F 17/00; G06F 17/30; H05K 7/00; G06F 1/16

(52) U.S. Cl. 705/3; 715/224; 707/803; 361/679.01; 361/679.26; 707/E17.045

(57) ABSTRACT

A method, system and device for storing and displaying medical records with a particular user. Once the medical records are inputted into a database, that information would be transferred to a portable device carried by or provided in close proximity with the user. Removable insulating strips are provided to complete an electrical circuit between one or more batteries and a circuit board. Once a circuit is created, contact will also be maintained between the one or more batteries and the circuit board. However, a timer is employed to power down the circuit, if an input button has not been engaged for a predetermined period of time. A second embodiment would allow a user in contact with a particular organization to include the user's identification number in a first relational database and the medical data in a second relational database.

### CROSS-REFERENCE TO RELATED APPLICATIONS

This present application claims the benefit of provisional patent application Ser. Nos. 61/273,995, filed Aug. 12, 2009; 61/254,622, filed Oct. 23, 2009; 61/254,719 filed Oct. 25, 2009; and 61/344,288 filed Jun. 23, 2010.

### FIELD OF THE INVENTION

The present invention is directed to a device, method and system for displaying medical information as well as a method and system for compiling, storing, improving the accessing of medical data.

### BACKGROUND OF THE INVENTION

The current age of micro technology has allowed an immense amount of information to be stored in either portable devices or at a central location. This stored data could include information relating to an individual's health such as, but not limited to, various medical conditions unique to that individual. This is quite important since if that individual becomes incapacitated and cannot verbally communicate with medical emergency personnel of the existence of pre-existing medical conditions and the like, the application of various techniques and medications used by both emergency personnel as well as physicians in a hospital setting could jeopardize the health of the individual and could ultimately lead to an untimely death.

Furthermore, even if the individual is not incapacitated, there are various situations that access to the medical history of the individual is important, such as in a school or university setting. In this instance, access to the individual's medical information must remain confidential as well as allow access to authorized medical or other personnel.

Therefore, in both situations, it is important to provide a device as well as system and method for accumulating an individual's medical history, storing that medical history in a secure central location and/or on a mobile device which would allow access to that information by both emergency as well as non-emergency personnel, yet providing the individual with peace of mind knowing that the information can be accessed by only an authorized person.

Prior U.S. patents and applications recite various systems and methods for maintaining personal health records of a user in a manner that allows these health records to be accessed in an emergency while allowing the user to control his or her privacy. For example, U.S. Patent Application Publication 2002/0026332 to Snowden et al discloses a password secured repository on a website for personal medical information controlled by the individual person and accessible by emergency personnel using a coded identification card and a PIN number. U.S. Patent No. 6,941,271 to Soong discloses a system whereby medical records stored on a site computer 110 can be accessed by a patient using a password. A patient can allow access to the records by others by the use of a password created by the patient.

Additionally, various prior art references disclose various devices allowing medical data to be stored and then displayed. For example, U.S. Pat. No. 5,877,742 to Klink et al discloses a medical identification bracelet that displays a patient's medical information. A personal computer houses the patient's information in formats and transfers this information to the bracelet. The bracelet has a screen where the information can be scrolled and read.

The U.S. Patent Application Publication No. 2004/0057340 to Charles-Erickson et al discloses a wrist worn medical information system and organizer having an LECD display screen. This information is internet based since screens of data can be obtained displaying different information.

However, none of these references describe a portable device which can download data stored in a central location which contains a power supply initiated for a period of time by emergency or non-emergency personnel. This power supply, when initiated, cannot be terminated. Furthermore, none of these references describes a system in which medical personnel or other individuals could access the medical information of the user stored at a remote central location using a password unique to the individual, the password stored at a location in the user's dwelling.

Additionally, the prior art does not illustrate a system which can be used in a non-emergency situation allowing security to the information when accessed by authorized personnel to be maintained.

These and other objects of the present invention will be described both in generalities as well as in particularities.

### SUMMARY OF THE INVENTION

According to one aspect of the present invention, there is provided an electronic device for displaying medical information in an emergency or non-emergency situation. The device has a feature that by its design, is prevented from being inadvertently powered on before power is needed. In another aspect of the present invention, the device has an irreversible power switch, wherein once actuated, allows power to be supplied to the device until the power source supplying the said power is drained or the device is powered down. In another aspect of the present invention, there are two or more such irreversible power switches. A timer is included which powers down the device after one or more of the power switches have been activated if there is no activity for a predetermined period of time.

In another aspect of the present invention, a user of the device and/or system and/or method of the present invention are associated with a password that is unique to the user.

In another aspect of the present invention, there is associated with the password one or more access devices such that a health care provider, using the password and access devices may obtain health care records of the user of the device.

In another aspect of the present invention, the device of the present invention is adapted in use to be carried by the user so that it may be activated without the user's consent if the user is unable to convey such consent.

In another aspect of the present invention there is provided a method and/or system for establishing and maintaining personal health records of a user of the device and/or method and/or system of the present invention in a manner that allows the user's personal health records to be accessed and/or disclosed and/or displayed in an emergency or in a non-emergency situation. The method and/or system includes providing a web site allowing the user to store one or more personal health records associated with the user and accessible by the use of a password associated with the user. In this description, specification and claims, the terms “individual,” “user,” and “consumer” are used interchangeably unless otherwise specified.

According to another aspect of the present invention there is provided a method for delivering to a health care provider or other entity the totality of personal health records of the individual. By the term “totality” is meant the personal health records, data, and other associated information that are stored and retrieved by the method of the present invention and are inputted, reviewed and stored by the user on an electronic database and optionally, imported, derived, or established from another source of information, e.g., a doctor, nurse, licensed medical practitioner, hospital and the like.

According to another aspect of the present invention there is provided a method for providing a consumer with the ability to access and collect personal health records associated with the consumer. The method includes assigning a phone number and/or password and/or email address individually associated with the consumer, such that with these identifying datum or data a healthcare provider or other appropriate individual can, even in the event that the consumer or user is debilitated, unconscious, unable to respond, senile, demented, incapacitated, or otherwise unable to communicate with the healthcare provider, be able to use the data or datum to access the consumer or user's personal identifying information and/or medical information. Using the password and/or other data recited in this specification, the healthcare provider will be able to access the user's personal identifying information and/or medical information on a website and server associated therewith, facsimile service or facsimile server, text message or text messaging server, or use of a voice transmission to access the records at a designated database and server therefore provided for the user.

According to another aspect of the present invention there is provided a method for using and/or evaluating and/or maintaining and/or updating personal health records and/or medical information of a consumer or a user in a manner that allows the personal health records and/or medical information to be accessed and the evaluated by a health care provider during an emergency or health care crisis of the user or consumer, or under circumstances wherein the user or consumer needs medical treatment. In this way the method will allow the healthcare provider to understand and use the medical data of a user or the consumer. In this aspect of the invention, the healthcare provider would be able to evaluate the integrity of the data. In another aspect of the present invention the medical data so provided to the healthcare provider is time stamped according to when the consumer input the data or when the data was input by the user into the system of the present invention.

It is understood that to participate or contract with civic, public or private organizations or activities, the disclosure of personal medical data is often required of a person as a condition precedent to contract formation of participation, with the medical information often transparently disclosed. In other words, the civic, public, or private organization has access to and can review the disclosed data.

Such a condition precedent of transparent disclosure of personal medical data can provide a disincentive to a person to make accurate and candid disclosure of such data, particularly if the disclosing person believes (correctly or mistakenly) that the organization's knowledge of such medical data may block, hinder, or prejudice contract formulation and/or participation. However, there also exists a need by the civic, public or private organization for full and candid disclosure of personal medical data which may be accessed by the civic, public or private organization when or if needed (e.g., in a medical emergency).

Thus, there exists a need to fulfill the condition precedent of candid disclosure, but not provide transparent access and review of the personal medical data by the civic, public or private organization prior to contract formation. There is a further need for full disclosure and a need to prevent unwanted or unneeded viewing or dissemination of personal medical data that could be damaging or embarrassing to the person associated with the data.

An object of the present invention is to improve the quality of disclosed medical data. The system and method of the present invention would include providing a first identification number of the person associated with that person's name. A first software relational database is maintained on an electronic communication with a first server having the capacity to store the first identification number and the person's name.

A second software relational database is provided and maintained on an electronic communication with a second server. Each of the first and second servers is in electronic communication. Both the first relational database as well as the second relational database is provided with the person's name and the first identification number. The second relational database is provided with a set of personal medical data of that person, provided by that person or another individual associated with that person. Once the personal medical data is inputted into the second relational database, the first relational database is notified that the set of personal medical data of the person is provided in the second relational database. While it is possible that the personal medical data can be transmitted from the second relational database to the first server and/or the first relational database, the present invention would operate even if this data is not transmitted from the second relational database to the first relational database.

In another aspect of the present invention, the set of personal medical data is accessed to the second server and/or the second relational database by a secured device.

According to another aspect of the present invention, the actions or acts of populating databases on servers are generally accomplished by using software routines or procedures as known to a person of ordinary skill in the art of electronic database management. By the term “server” is meant a computer with accompanying executable software that controls one or more features and/or functions, e.g., file retrieval and storage communications between servers, application server functionality, web server, and/or database server.

According to another aspect of the present invention, the first relational database and first server are associated with, owned by, or used by a first organization or first legal person desiring or requiring disclosure of medical information of the person. For example, a governmental organization, school district, college or university, civic group, neighborhood or private group hosting or sponsoring athletic events, and the like may be such an organization to require such a disclosure.

According to another aspect of the present invention, the second software relational database and/or or second server are in direct electronic communication with the person associated with the set of personal medical data. The communication is generally secured or encrypted and/or private communication.

According to another aspect of the present invention, typically the identification number may be a social security number, a driver's license number, a passport number or an assigned number (by an organization). The first identification number may be a randomly generated number.

Generally, and in another aspect of the present invention, the first relational database stores other personal information that identifies the person of whom personal medical data is required, which other personal information includes one or more of the following features: date of birth; place of birth, parent or parents' or guardian's name(s); social security number, passport number, driver's license number, sibling(s) name; sibling(s) ages; children's name(s); educational history, including name(s), address(es) and contact information of prior institutions of learning, including secondary schools, work history and/or employment history; prior academic performance data and the like.

According to another aspect of the present invention, the second software relational database operates on the second server and is operated by a second organization or second legal person. In this aspect, the first organization has no access or right to access to the personal medical data provided by the person.

According to another aspect of the present invention, there is provided an authentication data set, which authentication data set is typically a subset of the said other personal information stored on the first relational database. For example, the authentication data set may comprise one or more of the following features: first identification number; date of birth; place of birth; parent or parent's or guardian's name(s); social security number; passport number; driver's license number, sibling(s) name; sibling(s) ages; children's name(s); educational history, including name(s), address(es) and contact information of prior institutions of learning, including secondary schools, work history and/or employment history; prior academic performance data and the like. The authentication data set may comprise from 1 to 20 features, or from 2 to 15, or from 3 to 10, or from 4 to 8; or from 1 to 3; or from 1 to 4; or from 1 to 5.

According to another aspect of the present invention, the person of whom the disclosure is required, or an agent of the person therefore, then is provided access and/or electronic communication and/or direct electronic communication with and/or to the second software relational database and/or the second server.

In the specification, the term “electronic communication” is generally understood to comprise communication by a web page shown on a web browser software program that codes a microcomputer or personal computer to operate to communicate by standard internet or hypertext transfer protocols and the like to communicate with a server. Such protocols and methods are known to the person of ordinary skill in the art. Such electronic communication may also be understood to take place by software protocols known as application programs that are hosted by a microcomputer, e.g., a hand held microcomputer such as an Apple® brand device, commercially known as an IPHONE® or IPAD®.

These and other features of the present invention will be described in more detail below in the Detailed Description of the Invention and in conjunction with the following Figures.

### BRIEF DESCRIPTION OF THE DRAWINGS

The following figures represent these and other aspects of the present invention and are as such non-limiting.

FIG. 1 is a first perspective view of the device of the present invention;

FIG. 2 is a second perspective view of the device of the present invention;

FIG. 3 is an exploded view of the housing and various parts of the device of the present invention;

FIG. 4 is an exploded view of certain components on a circuit board of the device of the present invention;

FIG. 5 is a cross-sectional view of the circuit board before actuation of the device of the present invention;

FIG. 5A is a cross-sectional view of the circuit board during actuation of the device of the present invention;

FIG. 6 is a typical image or card of data as displayed on the device of the present invention;

FIG. 7 is a typical image or card of data displayed on the device of the present invention;

FIG. 8 is a typical image or card of data displayed on the device of the present invention;

FIG. 9 is a block schematic diagram of the device of the present invention;

FIG. 10 is a block diagram of a typical process to utilize the device and methods of the present invention;

FIG. 11 is a flowchart for inputting information of the user into the system by a first embodiment of the present invention;

FIG. 12 is an artistic rendering of a step in the method and an aspect of the system of the present invention;

FIG. 13 is an artistic rendering of a step in the method and an aspect of the system of the present invention;

FIG. 14 is an artistic rendering of a step in the method of the present invention wherein data is transferred to the device of the present invention from a central storage and retrieval server and database via the internet or worldwide web;

FIG. 15 is an artistic rendering displaying different cues that devices and/or aspects of the methods and systems of the present invention may be utilized;

FIG. 16 displays the actuation of the device of the present invention;

FIG. 17 displays a use of the device of the present invention;

FIG. 18 displays a use of the device of the present invention;

FIG. 19 displays different text materials useful as a cue in the method and system of the present invention;

FIG. 20 displays a flow chart describing a software process for translation of the medical data to images for in the device, method and system of the present invention;

FIG. 21 is a flowchart illustrating the operation of a second embodiment of the present invention;

FIG. 22 is a block diagram showing the operation of the second embodiment of the present invention; and

FIG. 23 is a flow chart for inputting information of the user into the system by a second embodiment of the present invention

### DETAILED DESCRIPTION OF THE PRESENT INVENTION

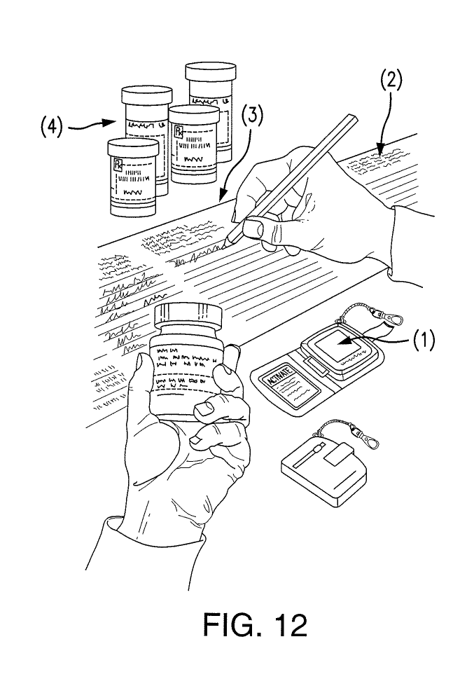

A general rendition of the system of the present invention is illustrated with respect to FIG. 12. A portable electronic device 1 would store medical data and other pertinent information of the present invention relating to a particular patient which has been transferred from a central database and displayed on the portable device 1. The individual or user associated with the portable device 1 must initially supply the medical information and other pertinent data to a server. This is accomplished using a worksheet 2 having instructions thereon allowing the individual to enter the appropriate medical information and other pertinent data unique to that individual. This information would include but is not limited to various conditions associated with that individual as well as various symptoms exhibited by that individual.

The worksheet 2 would include instructions 3 assisting the user in entering the aforementioned conditions and symptoms which are cumulatively the medical history of that individual. The healthcare information described in the specification would include “medical records”, “medical information”, “personal medical information” and “medical history”. This medical information would also include the medication 4 taken by the individuals.

For example, the user is instructed to gather research and prepare his or her personal identifying information and medical records, including one or more of the following data or features: name, address, phone number(s), email address(es), whether the user is an organ donor, date of birth, gender, ethnic background, height, weight, eye color, hair color, blood type, medication 4 taken either over-the-counter or by prescription, allergies, medical history and/or current or past medical conditions, emergency contacts, primary and secondary or specialty physicians, immunizations including the date given and the anticipated or expected expiration date, insurance information, including policy information, carrier and the like. The user may supply other information, for example, the location of the user's will and/or medical power of attorney or financial power of attorney, any specific religious beliefs or medical directives desired that could be used by treating medical personnel to modify, include or exclude medical treatment, information concerning the care of a pet, companion or relative, and the like.

The user will be assigned a unique password. This password may be randomly generated or chosen by the user. The term “password” also refers to the terms “pass code”, “unique code” or “lifepin”.

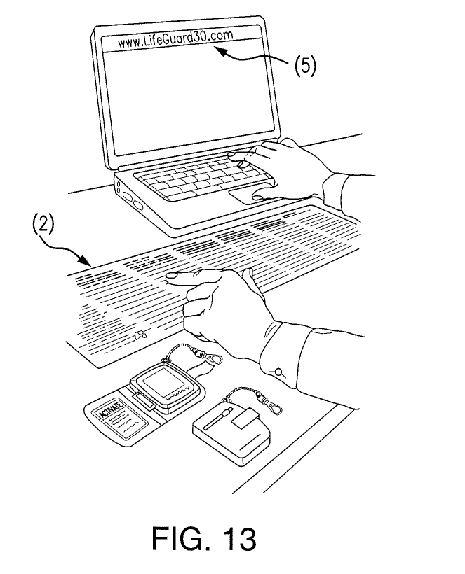

According to another feature of the present invention, and with reference to FIG. 13, after optionally having filed out the worksheet 2 prior to logging onto a website 5, the user then proceeds to the website 5 via the internet or world wide web, for example, to the website www.lifeguard30.com, wherein the user provides the password and/or optionally, another identifying code (e.g. an electronic email address) to access the site, verifying their subscription to a medical records storage and retention service, e.g. the lifeguard30.com service or www.lifepin.lifeguard30.com service. The user is then instructed to use the worksheet 2 to guide the user to input his or her personal identifying information, upload a photo of the user, and/or place their personal identifying and/or medical information into a relational database using various online forms in FIG. 13.

The various online forms used to prompt the user to provide the website 5 with the complete medical history of the individual would involve a number of questions. For example, the forms would instruct the individual how to upload a photo from his or her computer. The inclusion of a photo is important since if the individual is incapable of responding to questions voiced by medical personnel, and the present invention would be utilized to display the medical history of that individual, the photo is important to insure that the medical device belongs to the incapacitated individual. The online forms would also instruct the individual to select an area within the photo to use as their profile. Once the user is satisfied with their selection, the individual's photograph would be saved.

Other information contained on these online forms would include, but are not limited to the individual's name, place of residence, landline or cell phone number, email address as well as languages spoken. Various physical attributes such as hair color and eye color, height and weight as well as ethniticity and the user's blood type could also be included.

The online forms would also prompt the user to list all over-the-counter as well as prescribed medication as well as their dosages. Additionally, the online forms would allow the individual to input any and all allergies.

The user will now be given the opportunity to include all past and present medical conditions and emergency contact numbers.

Furthermore, the individual would enter any and all of their primary physicians as well as specialists both past and present. The individual would also be given the opportunity to input any and all immunizations they have received as well as the date of these immunizations.

Another online form would allow the individual to enter primary and secondary insurance information.

Yet another online form would allow the individual to enter any miscellaneous information that they feel would be important. This would include, but is not limited to any medical directives or religious beliefs that could dictate their treatment as well as to list any animals that they live with in case of hospitalization as well as contact information to take care of their pets.

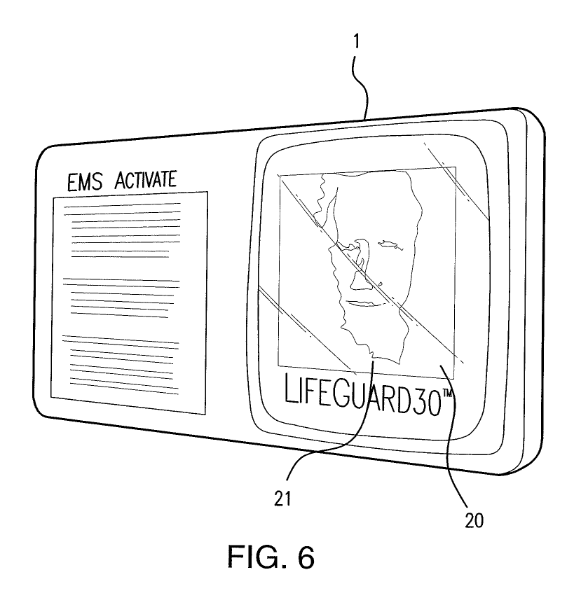

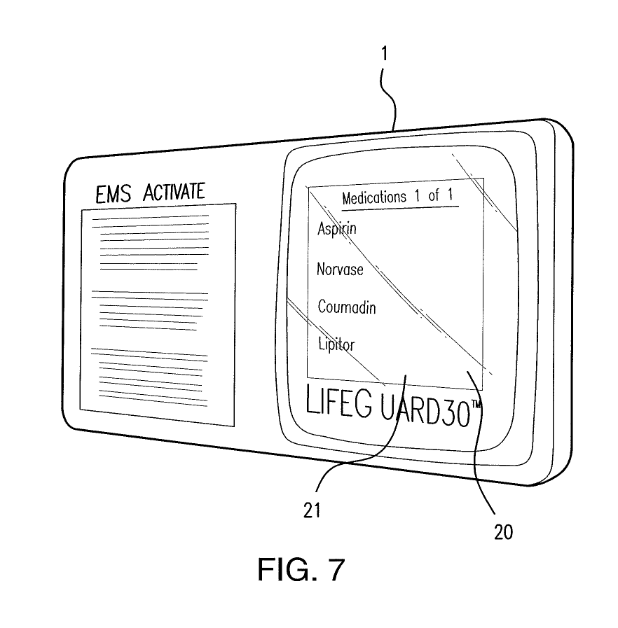

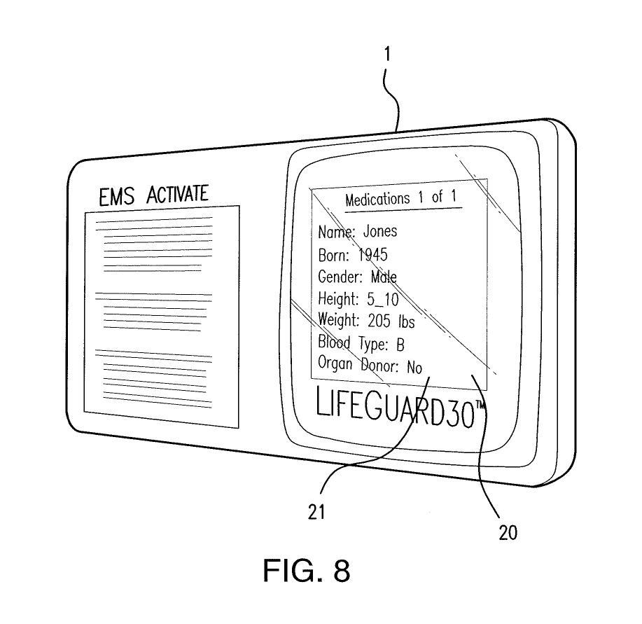

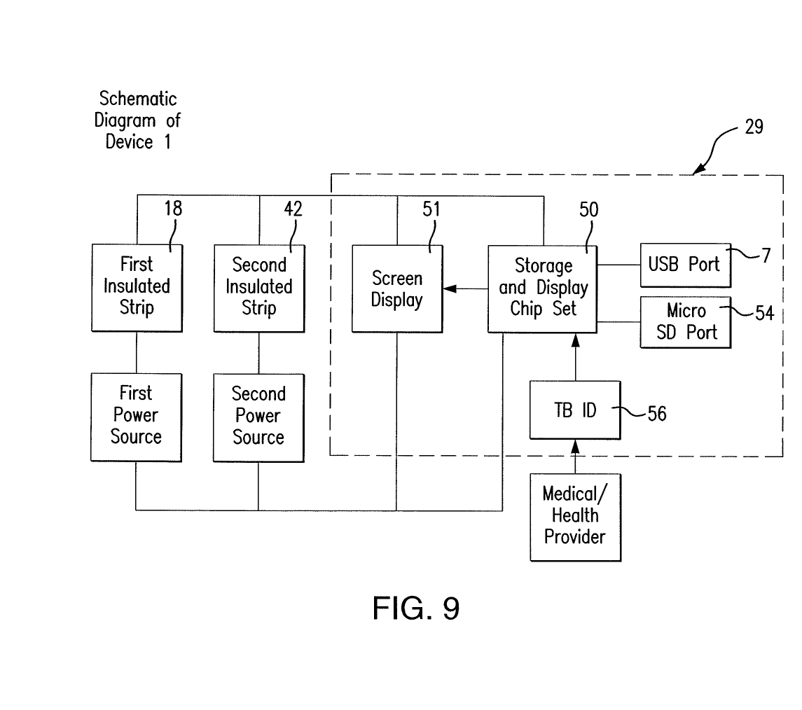

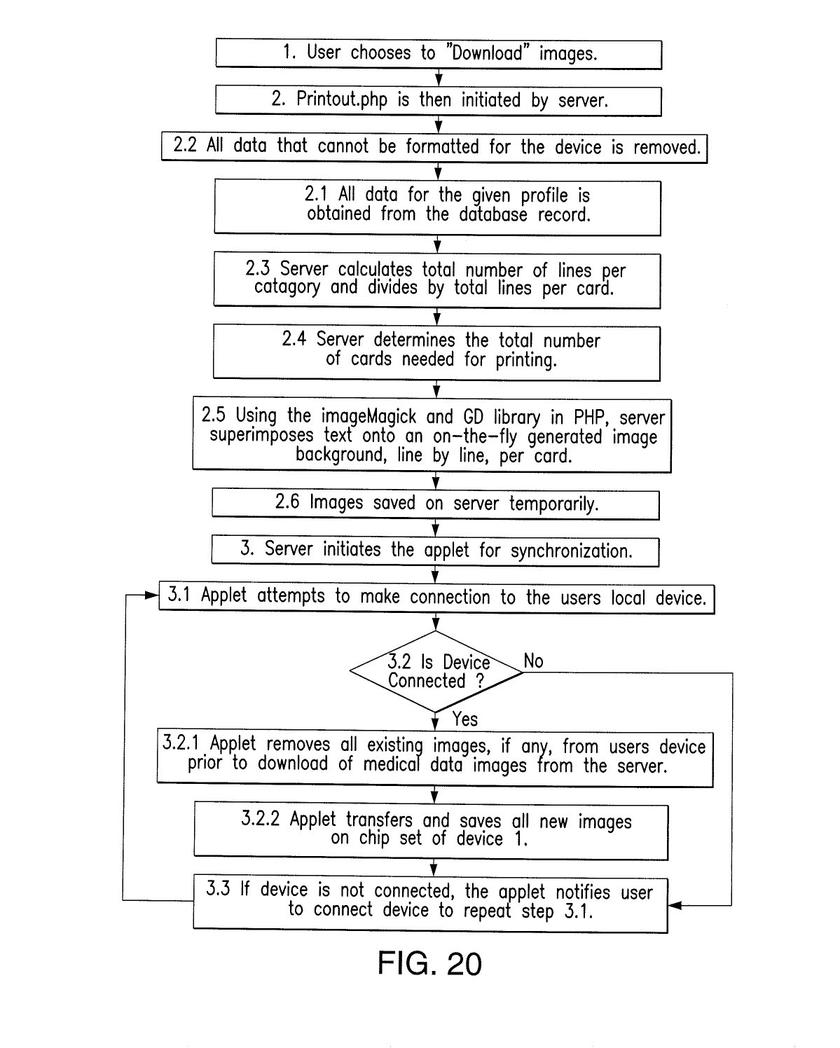

According to another feature of the present invention, and with reference to FIG. 20, FIG. 6, FIG. 7 and FIG. 8, the information that the user has input into the database is converted to one or more image files, e.g., .pdf files, .bmp files, .tiff files, or image files of other formats which conversion is known to a person of ordinary skill in the art. Generally, the formatting of the electronic storage (the digital image storage and display chip set 50—see FIG. 9) of the device of the present invention is subdivided into “cards”. By the term “card” is meant the amount of image data of a screen display 51 that can fit on the screen 21 of the device 1 of the present invention at one time. Generally, the number of cards formatted for the device of the present invention is from 10 to 200, or from 15 to 100, or from 20 to 80, or from 25 to 50.

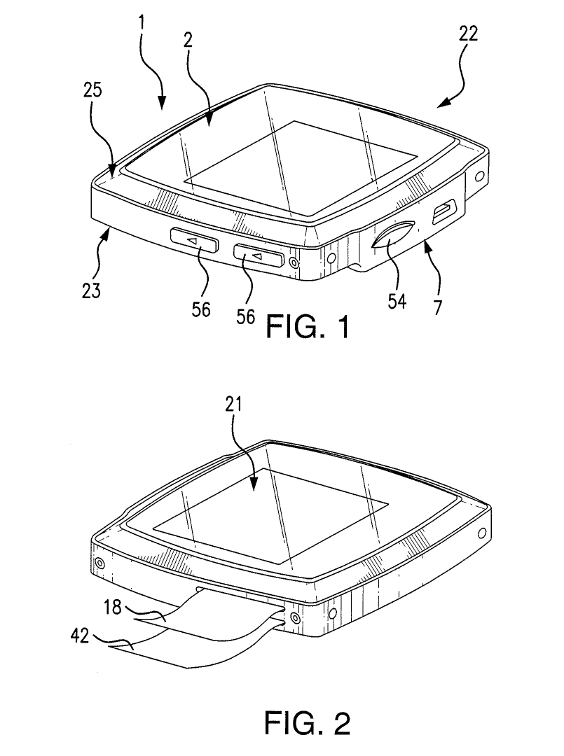

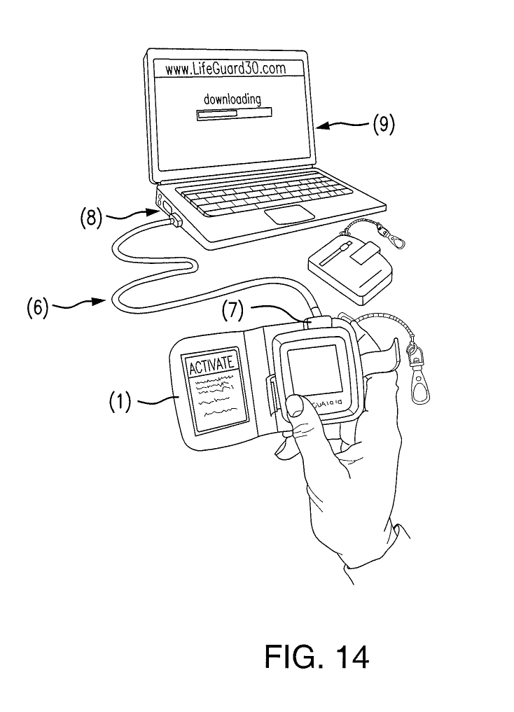

According to another feature of the present invention, and with reference to FIG. 1 and FIG. 24, after inputting all the information into the database, the information in the database can be transmitted to the device 1, where it is stored in a storage display chip set 50 shown in FIG. 9. This is accomplished by having the user connect the device 1 to a USB connecting cord 6 (see FIG. 14) via port 7 and connect the squared end of the USB connecting cord to a USB port 8 of a microcomputer 9 connected to the internet. This allows the device 1 to access a website, e.g. www.lifeguard30.com and via the established USB connection and internet connection, after processing the personal identifying information, a server, via the website, e.g., the lifeguard30.com website, and software program(s) thereon, downloads the produced one or more image files of the user's medical information onto a storage and display chip set 50 of device 1 via the USB connection.

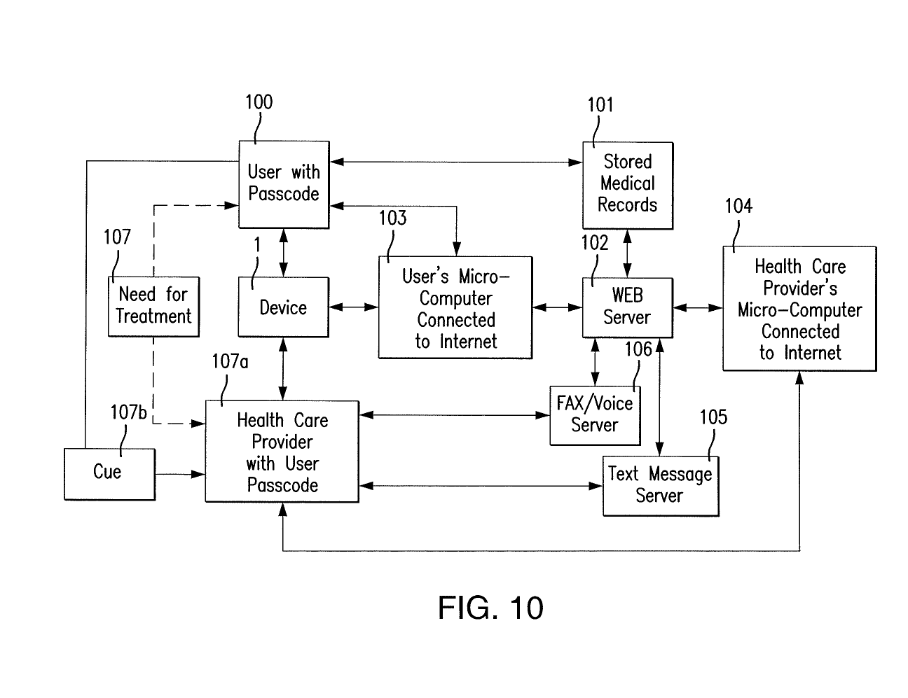

In reference to FIG. 10, a user 100 is provided with a unique password or passcode associated with the user. Using, inter alia, the password, the user goes online to store his medical records on a relational database 101 as previously described. The user connects to a central web server 102 via a microcomputer that is preferably connected to the internet 103 and uses interactive software to create his stored medical records on the database 101. Subsequently, the user's microcomputer is connected to the device 1 which receives translated image cards of the healthcare records stored on the database 101.

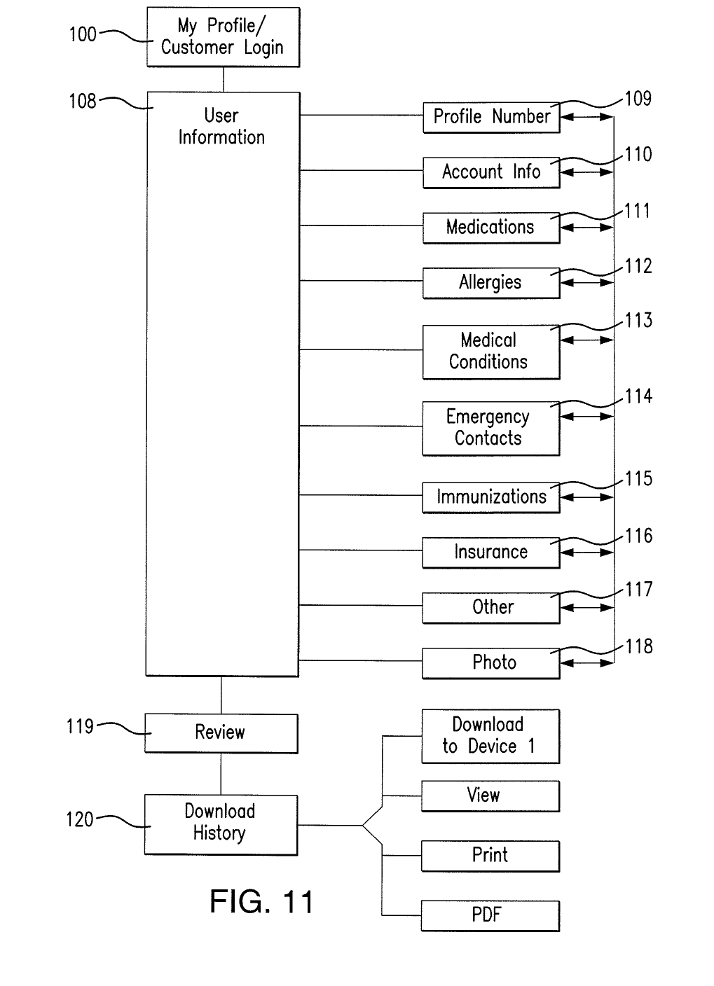

As shown in FIG. 11, the customer or user 100 is provided an opportunity to input user information, including personal identifying information and/or medical information 108. The user will have access to various forms or sub-screens, wherein the user may input his password 109, his account information 110, his medications 111, his allergies 112, any past or present medical conditions 113, emergency contacts 114, immunizations past and present 115, insurance information past and present 116, any other miscellaneous information 117 and a photo 118 of himself such that the healthcare provider 107a may be able to identify the user 101 correctly and use the pass code which is listed on, or associated with, the device 1 or associated with the user via the system of the present invention. After inputting all data 108, the data goes to a review phase after processing 119 allowing the user's information to be reviewed by the user or personnel having access to the stored medical records. The system would then produce image files that are then downloaded and viewed, printed or put into PDF form to be placed in the user's computer files or to be downloaded via the mechanism of the present invention to be stored in the device 1. The process of the invention also comprises formatting, printing, and mailing the medical data by paper mail, e.g., U.S. Mail, Fed Ex, or other ground delivery methods known to those of ordinary skill in the art. The process of the invention also comprises mailing a wallet identification card comprising the user's password and/or a photo of the user and/or a printed means to access the user's personal identifying information and/or medical records. The user's password and photo could be physically attached to the device 1, or posted at a location in the user's residence, such as a wall or refrigerator.

According to another feature of the present invention, with reference to FIG. 20, the process of uploading data and downloading image files to the device 1 is a complete process in that the website will not allow the user to finish an input and/or update session until the website has verified via software computer subroutine that the one or more image files so produced or edited has been successfully downloaded to the storage and display chip set 50 as described in FIG. 9.

FIG. 20 illustrates a flow chart showing how the user can properly download his medical information onto the device 1 to be stored in the storage and display chips set 50. The user accesses the server through the USB port 7 on the device 1 connected to the user's computer which in turn is in connection with the server via the internet. The server will then initiate the download by checking the password of the user and reviewing the appropriate medical records. All data that cannot be formatted will then be removed. Utilizing the appropriate software, the server would then be able to formulate the data to be downloaded into the user's device by providing a number of “display cards”. Each “display card” relates to the information that is able to be displayed and viewed by the user at one instance. As can be appreciated, based upon the size of the display and the type of medical information which was inputted by the user, the complete medical information to be viewed by the user or any medical personnel is accomplished only by sequentially viewing a plurality of screen images. This is accomplished by the server calculating the total number of lines per type of medical information and dividing this number by the total lines of the card. The server would then determine the total number of cards needed for printing as well as viewing.

The server would then superimpose the text onto an on-the-fly generated image background line by line per card and temporarily save these images on the server in that format. It is to be appreciated that the medical information for a particular user is not stored in the server in this manner. This particular process describes the manner in which the medical profile information will be downloaded and sent to the user's device 1.

Once the images are saved, the server would initiate an applet for sequentialization and would then attempt to connect to the user's device 1. If this is accomplished, any existing images contained in the storage and display chip set 50 would be removed and be replaced by the new images.

If the applet cannot properly contact the device 1, the user would be notified and would be instructed to again attempt to connect the server to the device 1.

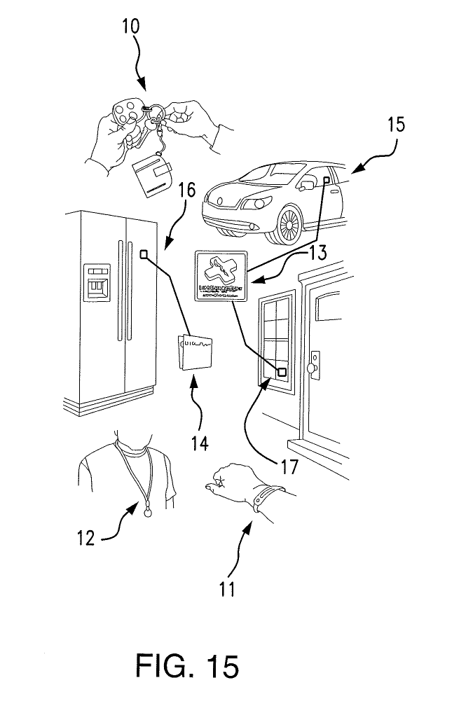

FIGS. 15-19 illustrate the manner in which the system according to the first embodiment of the present invention would operate. For example, as shown in FIG. 15, after the download process has been completed, through the use of the user's microcomputer 5, the user will be instructed to connect the device 1 to various personal affects 10 such as a key chain, purse or other personal items.

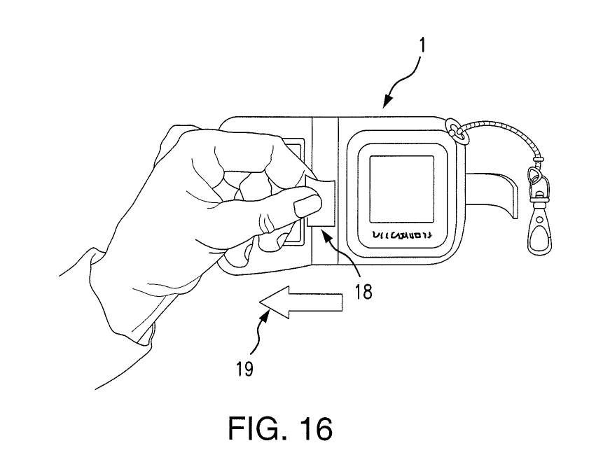

As previously indicated, the user would be provided with a unique password which is required to access the information maintained in the server. This password could physically be attached to the server or may be carried or worn to allow the user to access the information in the server or, if the user is incapable of doing so, allowing medical personnel or other individuals to access the server using the password. For example, the user may optionally wear a bracelet 11 displaying the password and/or a lanyard or necklace 12 comprising a piece of jewelry or medallion which would also include the password. In another embodiment, the password may be provided in a wallet identification card mailed to the user or could be in the form of a placard 13 placed by the user at a conspicuous and/or frequently visited location, such as the interior surface of a window of the user's car 15, within the user's home or dwelling, such as a refrigerator door 16 as well as the interior surface of the window of the home or dwelling 17. FIGS. 16-18 show how the device 1 is activated as will be subsequently explained to display the user's medical information.

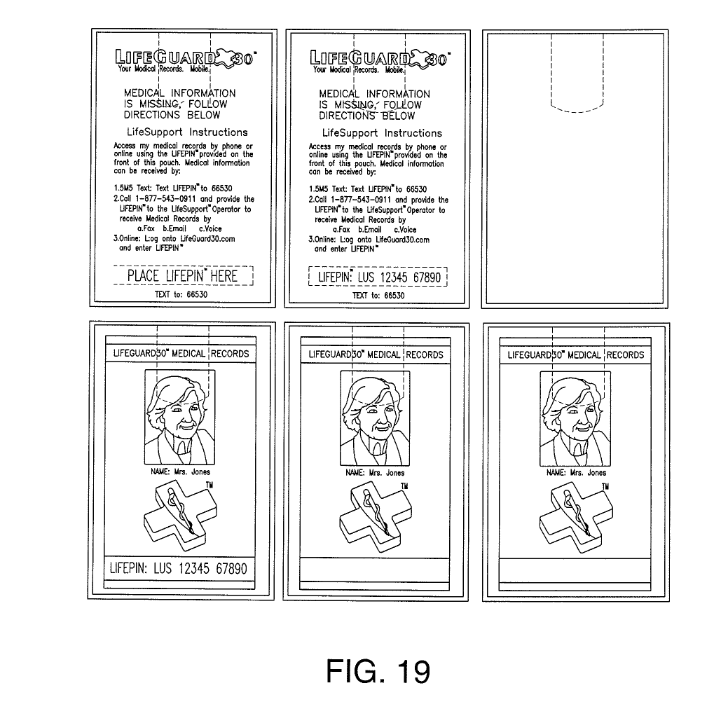

In another aspect of the present invention, there is also associated and displayed with the password a placard shown in FIG. 19 having a website, phone number, text message number, facsimile number and the like applied thereto as well as directions for allowing the medical personnel or other individual to access the individual's medical records even if the device 1 cannot be located. This would involve contacting the appropriate website online or utilizing a telephone utilizing the user's password. Additionally, the lanyard 12, placard 13, or bracelet 11 could typically display the manner of accessing the online records of the user as well as the password.

In one embodiment of the present invention, the user, after having established his account online with the website, generally may place the placard in a translucent or transparent sleeve 14, such sleeve being mounted on or in the user's home, place of business, church where conveniently and conspicuously available, e.g., an appliance, a wall, a refrigerator, a freezer and the like. In order to avoid invasions of privacy, the user is exhorted and instructed that all publically available placards alert medical and public safety personnel to the existence of the device and/or system of the present invention on or within the normal reach of the user. As such, publically available placards would not generally contain the password of the user. Optionally, the printed information so mailed to the user may be placed in the sleeve 14 in addition to, or without the placard 13.

In another aspect of the present invention, and with reference to FIG. 10, should there become a need for treatment 107 of the user 100, a healthcare provider 107a or other authorized personnel can utilize the password of user 100 provided on the device 1, or a cue 107b, e.g., lanyard 12, bracelet 11 which cue the device also comprises the associate access means. The healthcare provider may then obtain healthcare information of the user by use of a web server 102, fax server/voice server 106, a test message server 105 and/or a microcomputer connected to the internet 104 to which the healthcare provider has access.

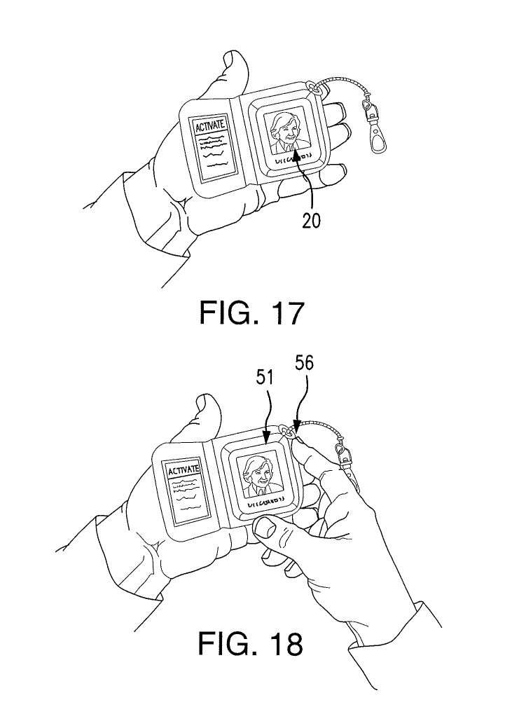

Alternatively, and preferably wherein the user or consumer is unable to provide medical information, and/or the healthcare provider cannot use the access means or the password of the user, and with reference to FIG. 16, FIG. 17 and FIG. 18, the device 1 is actuated by pulling a first insulating strip 18 in a direction 19 out and away from the device 1. By pulling the strip 18, an electrical circuit is completed within the device 1 allowing the device 1 to be energized and thus display image information 20 is provided on screen 21 to the person so actuating the device 1. It is important to note that the device 1 is activated without the healthcare personnel knowing the unique password of the user.

According to another feature of the invention, the system includes a subroutine to prompt the user to update his or her personal and/or medical information from time to time. For example, the system may include a software subroutine that accesses the database and determines that a user prompt for updating the medical/personal information should be sent to the user. The system prompts the user from once a month to once per year, then from once per month to once per every three months, and from once per month to about once per two months.

According to another aspect of the present invention, the image files downloaded to the device 1 also include one or more time stamps such that a medical provider accessing the medical records of the user may have the latest information input by the user and the medical records of the user can be evaluated for timeliness and appropriateness for diagnostics and treatment purposes.

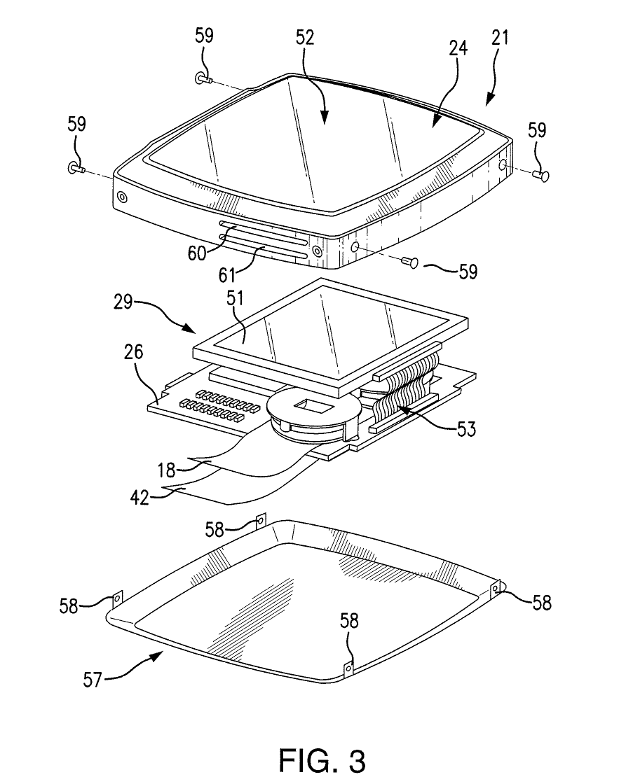

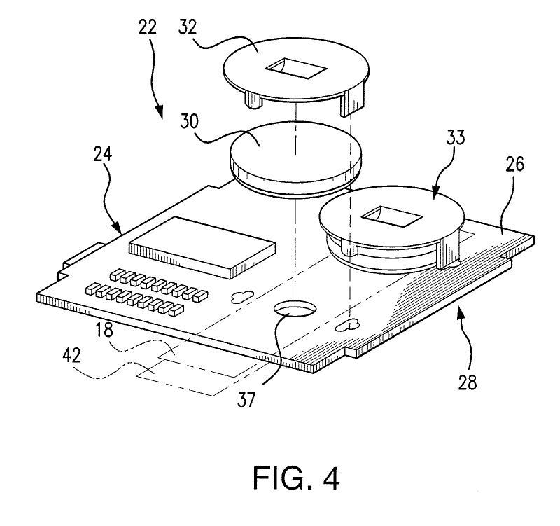

FIGS. 1, 2, 3, 4, 5 and 5a illustrate the construction of the device 1. This device includes a housing 23 having an inner surface 24 and an outer surface 25, a circuit board 26 having a front side 27 and back side 28, mounted to the housing on the inner surface 24 of the housing. A digital image display device 29 is mounted on the circuit board 26 such that while the device is in use the digital image display device provides images visible outside the housing. A first electrical power source and a second electrical power source is mounted within housing 23 such that the first and second power sources are independently and operably connected to the digital image display device 29. In this manner, the first and second power sources may power the digital image display device either together or independent of one another.

In one embodiment of the present invention, the first power source comprises batteries 30 and 31 having appropriate contacts inserted into battery receptacles 32 and 33, respectively, both receptacles being mounted on the front side 27 of circuit board 26 and forming part of the first electrical circuit which in use serves to power or energize the digital image display device 29. The batteries 30 and 31 are held in place by pressure applied from bias members 35 and 36. The bias members are operably and electrically connected to the battery receptacles 33 and 34 respectively, the bias members thus forming part of the first electrical circuit. The bias members 35 and 36 are so biased by the presence of the batteries 30 and 31, and thus apply pressure to the batteries 30 and 31 in direction 41 to press the said batteries 30 and 31 upon contact points 37 and 38, respectively. The insulating strip 18 is positioned between batteries 30 and 31 and contact points 37 and 38 and serves to interrupt the first electrical circuit. The insulating strip extends from the batteries 30 and 31 through slot 60 and outside the device housing 23 where it may be grasped by the human hand. Removing the insulating strip 18 by hand 39 in a direction away 40 from the batteries 30 and 31 complete the first electrical circuit between the contact points 37, 38 and the contact points of batteries 30, 31 and the digital image display device is actuated, energized, powered and/or usable to display medical/personal information to the user. The completion of the electrical circuit will provide power to the storage and display chip set 50 as well as the display.

The batteries 30 and 31, contact points 37 and 38 and battery receptacles 32 and 33 may be adapted such that the batteries 30 and 31 are in a series configuration or in a parallel configuration within the circuit as is known to a person of ordinary skill in the art.

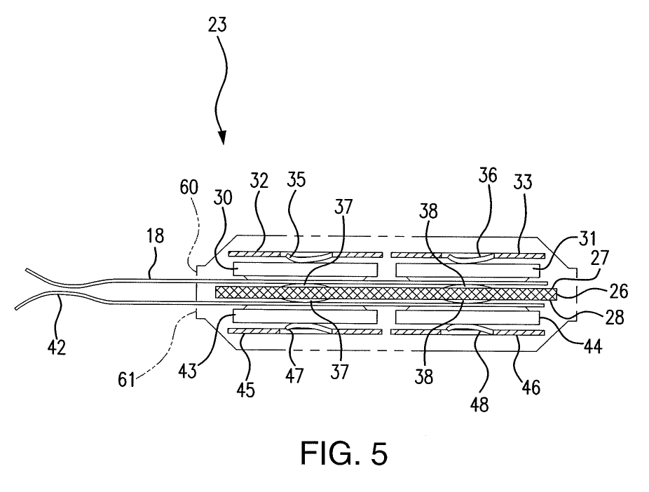

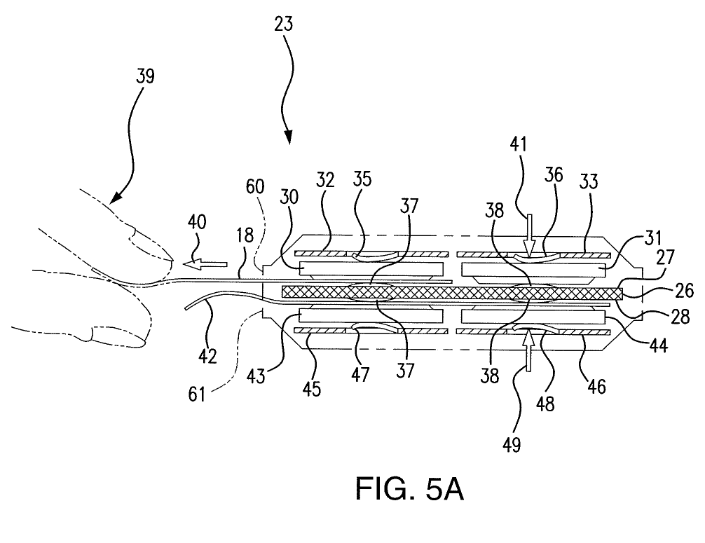

Optionally, if the batteries 30 and 31 are in parallel configuration, then insulating strip 18 may be grasped and withdrawn to a partially removed position shown in FIG. 5a. In this position, battery 31 is solely used to power device 1 assuming it is of sufficient voltage by itself to power device 1. In this manner, an individual battery of a parallel arrangement of batteries may be used to power the device 1. When battery 31 cannot power device 1 itself, then insulating strip 18 is completely removed allowing batteries 30 and 31 to power the device.

In another embodiment of the present invention, there is provided a second electrical power source comprising batteries 43 and 44 having appropriate contacts inserted into battery receptacles 45 and 46 respectively, both receptacles being mounted on the back side 28 of circuit board 26 and forming part of the second electrical circuit which in use serves to power or energize the digital image display device 29 as well as the display chip set 50. The batteries 43 and 44 are held in place by pressure applied from bias members 47 and 48. The bias members are operably and electrically connected to the battery receptacles 45 and 46 respectively, and form part of the second electrical circuit. The bias members 47 and 48 are so biased by the presence of the batteries 43 and 44, and thus apply pressure to the batteries 43 and 44 in direction 49 to press the batteries 43 and 44 upon contact points 37 and 38, respectively. The contact points are unitary in design and extend from above side 27 to below side 28. An insulating strip 42, positioned between batteries 43 and 44 and contact points 37 and 38 serves to interrupt the second electrical circuit. The insulating strip extends from the batteries 43 and 44 through slot 61 and outside the device housing 23 where it may be grasped by the human hand. Removing the insulting strip 42 by hand 39 in a direction 40 away from the batteries 43 and 44 completes the second electrical circuit between the contact points 37, 38 and the contact points of batteries 43 and 44 and the digital image display device is actuated, energized, powered and/or is usable.

The batteries 43 and 44, contact points 37 and 38 and battery receptacles 45 and 46, may be adapted such that the batteries 43 and 44 are in a series configuration or in a parallel configuration within the circuit as is known to a person of ordinary skill in the art.

Optionally, if batteries 43 and 44 are in parallel configuration, then insulating strip 42 may be grasped and withdrawn to a partially removed position such that battery 44 is solely used to power the device if battery 44 assumes it is of sufficient voltage to power the device 1. In this manner, an individual battery of a parallel arrangement of batteries may be used to power the device 1. When battery 44 is unable to power device 1, then insulating strip 42 is completely removed and batteries 43 and 44 may power the device 1.

In general, the first and/or second power sources comprise one or more individual batteries, for example from about 2 to about 20 V, or from about 2 to about 10 V, or from about 2 to about 8 V or from about 2 to about 5 V, or from about 2 to about 3 V batteries known to those of ordinary skill in the art. For example, a lithium battery, e.g., about a 2 to about 3 V Lithium-manganese oxide batteries, having a cathode of manganese dioxide and an electrolyte of lithium perchlorate in propylene carbonate and dimethoxymethane. Generally of from about 2 to about 7 V, or from about 2 to about 6 V, or from about 2 to about 5 V, or from about 2 to about 4 V or from about 2 to about 3 V; or from about 3 to above 6 V or from about 4 to about 6V is required to energize and/or use the device.

Strips 18 and 42 are composed of an electrically insulating material constructed from a plastic material. Examples of the insulating material include, but are not limited to polyethylene, cross linked polyethylene, polypropylene, polyvinyl chloride and modified or unmodified polytetrafluoroethylene. The removal of the first insulating material strip 18 serves as an irreversible power switch. The removal of the second strip of insulating material 42 also serves as an irreversible power switch. The device may be powered on if the batteries in the first electric circuit are drained, again later by completing the second electrical circuit. In this manner, each separate strip of insulating material serves as an “on” switch and the device remains on until the power source so actuated is drained of power or the circuit is powered down by inactivity as will be subsequently explained. This is true since the insulating strips 18 and 42 can only move in the direction of arrow 40, and therefore once contact is made between the contact points and one of the batteries, that contact point cannot be disengaged from its respective battery. The strips 18 and 42 are generally of differing or the same length and optionally of differing colors and/or translucent. The strips are colored, if at all, to prevent a color-blind user from being unable to actuate the device 1.

The number of power sources generally ranges from 2 to 6, or from 2 to 4; or from 2 to 3; and 2 or 1. The number of individual batteries ranges from 2 to 20, or from 2 to 16 or from 2 to 10, or from 2 to 8, or from 2 to 4, or 2, or 4. The number of batteries per power source ranges from 1 to 10, or from 1 to 9, or from 1 to 8 or from 1 to 7, or from 1 to 6, or from 1 to 5, or from 1 to 4, or from 1 to 3, or from 1 to 2, or 1, or 2.

The housing 23 is enclosed by joining a backing 57 to the housing 23 by any connecting means known to a person of ordinary skill in the art. The housing and backing are easily joined by using screws or rivets or an equivalent joining technology to connecting posts 58 through holes proved on the exterior of the housing.

With reference to FIGS. 1-5a and FIG. 9, an electrical circuit of device 1 includes the digital image display device 29, the digital image storage and display ship set 50 and the digital image display screen 51. The display screen 51 is generally placed in registration with an opening 52 in the housing 23 and is connected to the digital image storage and display chip set 50 by a standard interface known to those of ordinary skill in the art. An example of a display screen is model RFD-144A01, manufactured by FRIA-LCD Co. Ltd. Of Shenzhen, China.

The digital image storage and display chip set 50 comprises multiple components that are mounted and interconnected by soldering the individual components onto the circuit board. FIG. 9 displays a block circuit diagram and its major components.

Information is delivered to the chip set by connection to a digital information source, e.g., a microcomputer, via a USB (Universal Serial Bus) interface port 7, or by insertion of an appropriate microchip loaded with digital information into a microchip interface port 54 such as a micro SD interface. The micro SD microchip, for example, is left in the device so that the information stored thereon can be accessed by the chip set.

Generally, the storage and display chip set comprises from about 128 megabytes to about 25 gigabytes of memory, or from about 256 megabytes to about 2 gigabytes of memory, or from about 512 megabytes to about 1024 megabytes of memory to store images for later display.

With reference to FIGS. 1, 9 and 28, a two-button input device 56 (“TBID”) is provided which is in communication with the storage and display chip set 50 so the user of the device may scroll, parse, examine and explore the images displayed on the screen 51 by the storage and display chip set 50. Such a TBID device is generally known to those of ordinary skill in the art. Other equivalents to TBID include a scrolling wheel. One or both of the input buttons 56 is used in conjunction with the insulating sheets 18, 42 to power the system. Once one of the insulating sheets 18, 42 is moved a sufficient distance to produce contact between at least one of the batteries and a contact on the circuit board, the system is powered on by depressing one of the input buttons 56. A timing circuit provided on the circuit board is provided to sense whether either of the input buttons is depressed for a period of time, such as, but not limited to 30 seconds. If no activity is sensed for this period of time, both the display and the display chip set including a processor will be powered down, thereby removing a drain from one or more of the batteries. Since insulating sheets 18, 42 cannot be moved opposite to direction 40, once electrical contact is established between one or more of the batteries and a contact on the circuit board, this contact will also be maintained. Therefore, if one of the input buttons 56 is depressed after the device has been powered down due to lack of activity for a period of time, the device would be powered up and the medical history or other information will again be provided on the display until no activity is sensed for the time period. If this occurs, the device will again be powered down.

The device 1 is manufactured by soldering all of the electronic components to the circuit board 26. All of the components run off of the storage and display chip set 50 including the onboard memory. The function of this chip set is to gather image data through the USB interface and store the image data on the chip set's onboard memory. The image data is stored so it can be viewed on the display such as a 128×128 display when prompted by the user. As previously described, the batteries are configured into two separate circuits each with a capacity to power the chip set with the onboard memory and display information for at least 40 minutes per dual battery bank.

The batteries are configured to remain dormant until the user or any other personnel physically changes their configuration by removing one or more of the insulating strips 18, 42. This process preserves the life of the batteries' optimum storage time. The insulating strips extend through the slots 60, 61 far enough for a user with even limited dexterity to grasp and remove the block from between the batteries, thereby completing the circuit. All of the device components are housed in a stainless steel and plastic storage container designed to protect the components from dirt, moisture and shock damage. The stainless steel portion of the housing is comprised of two clam shell style plates that each affix firmly to a plastic ring portion with a plurality of small screws. When completely assembled, the housing becomes extremely sturdy and provides a protective cover for the electronic components and a sturdy structure for the interface components to attach.

After the user has downloaded the medical and personal information into the storage and display chip set and memory 50, the device can now be accessed to display the medical and personal information thereon. Placards would be affixed to various convenient locations in the user's dwelling to inform any medical personnel of the existence of the device 1. It is important to note that once the device 1 is located, the medical personnel need not be aware of the user's password since the medical information will be displayed upon completing the circuit by either completely or partially moving either one or both of the insulating strips 18, 42.

Since the information contained in the device 1 is also retained in a secured server, if medical personnel would find the user in a comatose state or in a state which would not allow the user to communicate with the medical personnel, and the device 1 cannot be located, the medical information can still be accessed by the medical personnel by using the password provided on the user's bracelet or lanyard or- similar device to contact the remote server through the use of any computer with interne access. The medical information would then be displayed on the computer screen and can be viewed, saved or printed. Alternatively, the medical personnel could use a cell phone or other device which can transmit or receive text information to retrieve the medical information. Finally, the medical personnel could use any telephone system to retrieve the medical records corresponding to the specific password from a telephone operator will read the information.

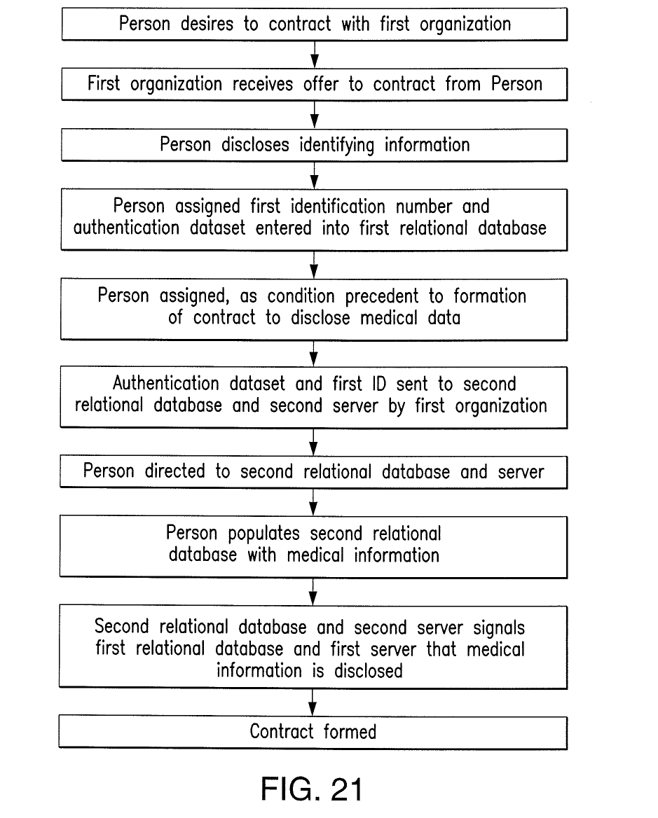

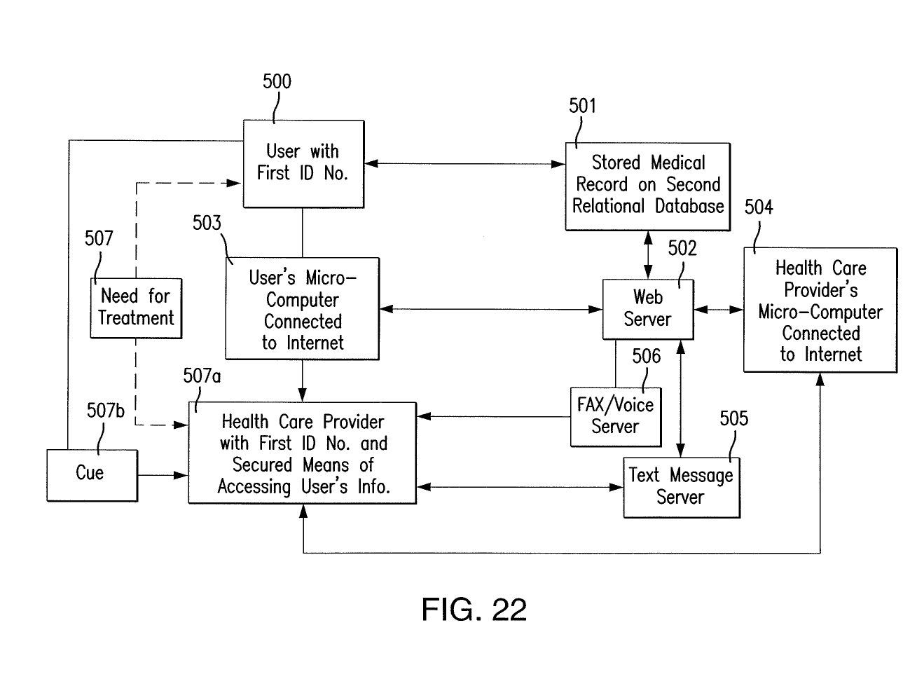

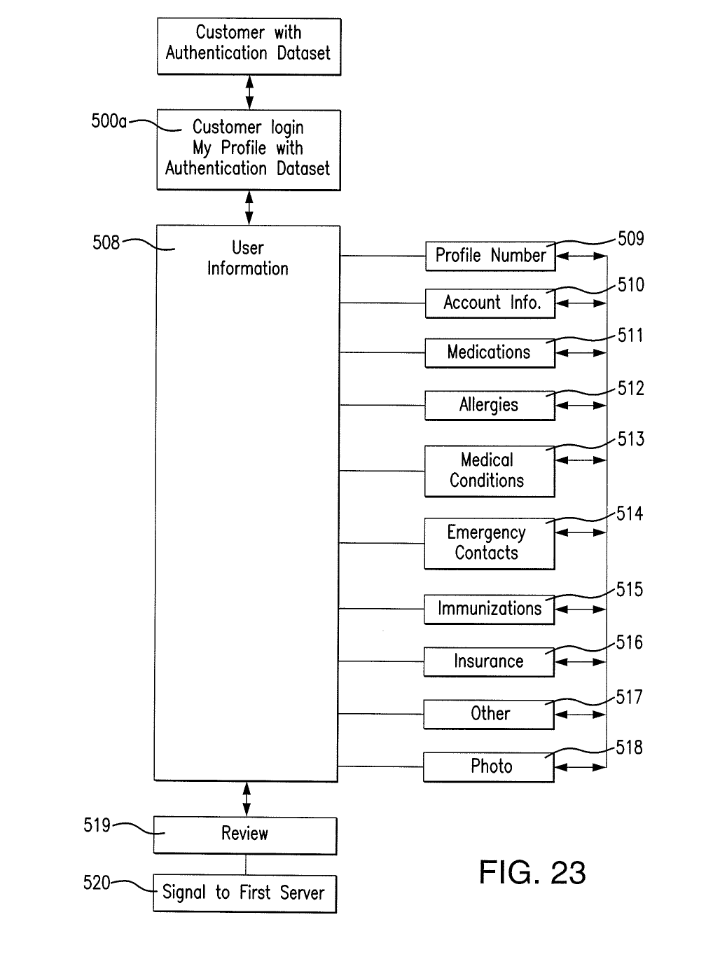

A second embodiment of the present invention makes reference to FIGS. 21, 22 and 23, with FIG. 22 having similarities to FIG. 10 and FIG. 23 having similarities to FIG. 11.

As described in FIG. 21, a person who wishes to contract with a first organization would be assigned a first identification number and authentication data set entered into a first relational database associated with a first server. The authentication data set and the first identification number is sent to a second relational database associated with a second server by a first organization. A user is then directed to a second relational database and the second server.

The user would then enter various information, such as personal and medical information, into the second relational database. The second relational database and second server would then signal the first relational database and first server that the appropriate information has been disclosed and a contract would be formed between the user and that first organization.

Similar to the first embodiment, as illustrated in FIG. 22, the user or person to whom disclosure is required, with respect to the second relational database may also be known as a “customer” or “user” 500. The user which is assigned an identification number would go online to store his or her medical records on the second relational database 501. Generally, the user would connect to a central web server 502 via a microcomputer 503 that is preferably connected to the internet and uses an interactive software to create his or her stored medical records on the database 501.

Once the user is on the web server 502, the user is provided an opportunity to input user information, including personal identifying information and/or medical information 508 as shown in FIG. 23. The user information screen includes access to various sub-screens wherein the user may input his profile number or password 509, his identification number (also may be referred to as a password) account information 510, his medications 511, his allergies 512, any past or present medical conditions 513, emergency contacts 514, immunizations past and present 515, insurance information past and present 516, any other miscellaneous information 517 and a photo 518 of himself such that a healthcare provider 507a may be able to identify user 500 correctly in case of emergency or routinely, as the case may be.

In another aspect of the present invention, the user is prompted to review and/or update the set of personal medical data for accuracy. The user 500 is also prompted for a communication address, e.g., email address, cellphone number with text messaging capability, postal address, or hand held microcomputer with an appropriate application program. The second database and/or second server may then remind the user by standard communication protocol, e.g., email, text message, or alert via application program, to update the user's medical information periodically, for example, from every 30 days to 180 days, or every 45 days to 120 days, or from every 60 days to 100 days.

In another aspect of the present invention, there is provided a second identification number associated with the person's name and first identification number, which second identification number is generated and assigned by a software subroutine residing on the second server and/or second relational database.

In another aspect of the present invention, the second identification number is generally not provided to the person of whom disclosure is required. The second identification number, in this way, is utilized by the second server and second relational database to track and store information accurately about the person of whom disclosure is required. A person of whom disclosure is required generally has no need for the second identification number. For example, the person of whom the disclosure is required may be a student at a university and the university requires (and needs), as a condition of matriculation, accurate personal medical information about each of its students. However, the person disclosing such data may use the authentication data set to update their personal medical information on the second server and second relational database. The second identification number can provide unsecured access to the personal medical information of a particular user.

In another aspect of the present invention, there is provided a means of obtaining the personal medical information in case of emergency, immediate need, or routinely. With reference to FIG. 22, a healthcare provider of or associated with the first organization 507a is assigned a specific access code and/or access device 507c to the second server and to the second relational database 501. For example, specific personnel of or associated with the first organization, with a need to know the medical information of the person disclosing such medical information may access the second server and second relational database by a secured path using the first identification number or other aspect of the authentication data set. The secured path includes one or more of the following features: a uniform resource locator (url) that is assigned to the first organization as a worldwide web or internet protocol electronic communication pathway to the second relational database; an application program that is hosted by a microcomputer, e.g., a hand held microcomputer such as an Apple® brand device, commercially known as an IPHONE® or WAD® wherein the application program require identifying information of the user in order to access the personal medical information of the person; a text message server in electronic communication with a text messaging device, wherein the text messaging server requires identifying information of he user in order to access the personal medical information of the person on the second server.

Typically, access to the stored medical records 501 is effected by the healthcare provider 507a using secure device 507c and a microcomputer 504 connected to the web server 502. The web server then accesses the second relational database and the stored medical records of user 500. The access to the medical records 501 may also be done via fax/voice server 506 and/or a text message server 505. In one embodiment, the servers 506 and 505 may communicate through web server 502 or may independently be routed to the second relational database 501.

In most instances, the need to know the medical information of the user may be generated by a need for treatment 507, typically an emergency, or a cue 507b. Examples of cues include identification cards, stickers, other visible or discoverable indicia of association with the first organization.

In one embodiment, the user may be a child at a school and the child has a medical emergency at the school.

In another aspect of the present invention, the privacy of the person's medical data is generally preserved. Access to the personal medical information of the user is restricted to personnel of the first organization. The number of times the medical information is accessed can be tracked electronically on the second server or second relational database by recording the number of times, and to whom, the access is granted. In this way, the fist organization can determine if misuse or abuse of the access is taking place.

In another aspect of the present invention, the statistical accuracy of the medical information of disclosure is improved. For example, over a population of persons of whom disclosure is required, the accuracy of information about one of the following is improved: pre-existing medical conditions; existence of sexually transmitted diseases; immunizations; past medical procedures, e.g. surgery; current prescription medications being taken; prior illegal drug use or prior drug use; and family health history.

In another aspect of the present invention, the person of whom the medical information is required may also elect to have access to the second identification number. In this way, if the second identification number is available to a medical service provider in an emergency, the person providing medical services may have a need to have accurate medical information about the person disclosing the data. In this way, the person of whom disclosure is required by the first organization has a concomitant or accompanying or associated incentive to insure he accuracy of the data.

Typically, at the end of the process of inputting the required information into the second server and second relational database, the person is given an option to purchase the second identification number, according to co-pending U.S. Provisional Application No. 61/254,719, filed Oct. 25, 2009 expressly incorporated herein. After purchasing the option and after inputting all data 508, the data goes to a review phase after processing 519 wherein and afterward the system provides image files that are then downloaded and viewed, printed or put into PDF form to be placed in the user's files or to be downloaded via the mechanism of the invention of provisional application Ser. No. 61/254,719, filed Oct. 24, 2009, that is to a personal medical information storage device, for example, storage device now described below the following non-limited examples.

### CONSTRUCTIVE EXAMPLE 1

A young man John Doe applies to Big State University, Virginia. As a condition of enrollment, John Doe fills out an application for matriculation into Big State University's undergraduate program.

Big State University requires as a condition of matriculation, a complete medical history for each student to be placed on file in case of medical emergency.

Big State University places all of John Doe's personal information into an electronic relational database accessible by its personnel on Big State University's mainframe computer and server (“first server”). Big State University creates an authentication data set comprising John Doe's name, his date of birth and social security number. The authentication data set is sent to a private company charged with collecting John Doe's personal medical informational. John Doe is prompted by big State University to visit the private company's website to begin the process of entering his complete medical history into forms supplied at private company's website.

John Doe enters an authentication data set at the Customer Login step 500a and after being allowed into the site (associated with the second server), John Doe enters his medical information according to the flow chart of FIG. 23.

At the end of the process, a signal is sent to the first server of Big State University that John Doe has successfully provided his medical information and is eligible for matriculation.

### EXAMPLE 2

John Doe gets inebriated at a fraternity party at Big State University. He is intoxicated with alcohol such that he cannot respond to fellow party goers, and emergency medical personnel are called to attend to John Doe. Paramedics arrive and examine John Doe for identifying information. John Doe is carrying his student identification card provided to him after matriculation containing a student ID number. Told that he is a student at Big State University, the paramedics utilize a specific URL via the world wide web to obtain the medical information that John Doe input into the private company server before matriculation. The paramedics treating John Doe are able to utilize medicines John Doe has taken in the past to appropriately safely treat him.

It is specifically intended that the present invention not be limited to the embodiments and illustrations contained herein, but include modified forms of those embodiments including portions of the embodiments in combinations of elements of different embodiments as come within the scope of the following claims.

What is claimed is:

1. A method for allowing access to medical and personal information of an incapacitated individual comprising the steps of:
assigning a unique password to the individual;
connecting the individual through the internet to a website having a central database;
prompting the individual in entering medical and personal information in said central database;
providing the individual with written information including said password and said website, said written information provided on a placard; and
affixing said placard to an accessible location in the individual's dwelling;
wherein emergency personnel finding the individual in an incapacitated state in his dwelling can access said medical and personal information through the internet to said central database through said website using said password provided in said placard to gain access to said medical and personal information.

2. The method in accordance with claim 1, further including the stop of providing the individual with a worksheet to physically enter said medical and personal information thereon prior to said connecting step.

3. The method in accordance with claim 2, further including the steps of:
utilizing a personal computer having a first display to allow the individual to contact said website; and
providing the individual with a plurality of online forms shown in said first display to enter said medical and personal information.

4. The method in accordance with claim 1, further including the steps of:
supplying the individual with a portable device having a memory and a second display;
connecting said portable device with said website;
downloading said medical and personal information from said central database to said memory of said portable device; and
activating said portable device for automatically displaying said medical and personal information on said second display.

5. The method in accordance with claim 3, including the step of:
periodically sending a communication to said personal computer to prompt the individual to update the medical and personal information provided in said central database.

6. The method in accordance with claim 5, including the steps of
updating the individual's medical and personal information provided in said central database;
downloading said updated medical and personal information from said central data base to said memory in said portable device, thereby replacing the medical and personal information previously stored in said memory of said portable device.

7. The method in accordance with claim 1, wherein said medical and personal information includes a photograph of the individual.

8. The method in accordance with claim 7, wherein said medical and personal information includes medications, medical conditions, allergies, immunizations and emergency contacts.

9. The method in accordance with claim 4, wherein said portable device is battery powered and further including the step of:
constructing said portable device to display said medical and personal information by providing an irreversible electrical connection between said battery power, said memory and said second display, said medical and personal information displayed on said second display until said battery power is drained or a timer senses inactivity and the portable device is powered down, thereby conserving battery power.

10. The method in accordance with claim 9, wherein said irreversible connection is created by removing an insulating sheet separating said batteries from a circuit board containing said memory.

11. The method in accordance with claim 9, containing the steps of:
providing said portable device with input buttons; and
depressing said input buttons to scroll through a series of screens provided in said second display, thereby showing the medical and personal information of the individual.

12. A portable device for displaying information, comprising
a housing provided with a first slot;
a display provided in said housing;
a circuit board having at least one contact provided within said housing, said circuit board provided with a memory;
a source of electrical power provided in said housing opposite said circuit board; and
a first sheet of insulating material provided with a first end and a second end, said first end extending through said first slot and said second end provided within said housing between said at least one contact of said circuit board and said source of electrical power, thereby preventing electrical contact between said circuit board and said source of electrical power;
wherein when said first end is pulled a sufficient distance away from said housing thereby removing said second end from between said contact of said circuit and said source of electrical power, an electrical circuit is produced between said source of electrical power and said circuit board allowing information stored in said memory to be shown on said display.

13. The portable device in accordance with claim 12, wherein said first sheet of insulating material can move only in a single direction, thereby ensuring said electrical circuit would always engage said at least one contact of said circuit board when said second end is removed between said source of electrical power, producing said electrical circuit.

14. The portable device in accordance with claim 12, wherein said source of electrical power comprises first and second batteries facing one side of said circuit board, said circuit board provided within a first contact opposite said first battery and a second contact opposite said second battery, wherein said electrical circuit is produced by pulling said first end of said first sheet of insulating material a first distance to remove said second end of said first sheet of insulating material from between said first battery and said first contact while maintaining separation between said second battery and said second contact, and further wherein said electrical circuit is produced by pulling said first end of said first sheet of insulating material a second distance greater than said first distance removing said second end of said first sheet of insulating from between said second battery and said second contact to allow contact between said first battery and said first contact and between said second battery and said second contact.

15. The portable device in accordance with claim 14, further including:
a second slot in said housing;
a third battery facing a third contact provided on the second side of said circuit boards;
a fourth battery facing a fourth contact provided on said second side of said circuit board; and
a second sheet of insulating material provided with a first end and a second end, said first end extending through said second slot and said second end provided within said housing between said third battery and said third contact, as well as between said fourth battery and said fourth contact, thereby preventing electrical contact between said third battery and said third contact as well as between said fourth battery and said fourth contact, wherein said electrical circuit is produced by pulling said first end of said second insulating material a first distance away from said housing to remove said second end of said second insulating material from said third battery and said third contact while maintaining separation between said fourth battery and said fourth contact, and further wherein said electrical circuit is produced by pulling said first end of said second insulating material a second distance greater than said first distance to allow contact between said fourth battery and said fourth contact by removing said second end of said second insulating sheet from between said fourth battery and said fourth contact.

16. The portable device in accordance with claim 15, further including a single receptacle for each of said batteries, each of said receptacles provided with a bias device forcing each of said batteries toward said circuit board.

17. The portable device in accordance with claim 12, further including a communication device provided between the portable device and the internet allowing said information to be transmitted between a central database and said portable device to be stored within said memory, allowing said information to be automatically shown on said display when said electrical circuit is produced.

18. The portable device in accordance with claim 17, further including at least one input device on said housing used to scroll through a number of screens showing said information on said display.

19. The portable device in accordance with claim 17, further including a timing circuit to power down said portable device when said at least one input device is not depressed for a predetermined period of time, thereby conserving said source of electrical power.

20. A method of securely storing and accessing personal information, comprising the steps of
a) providing a first identification number of a person associated with the person's name;
b) providing a first software relational database maintained on and in electronic communication with a first server, wherein said first relational database stores the first identification number and the person's name;
c) providing a second software relational database maintained on and in electronic communication with a second server and wherein said first and second servers are in electronic communication with each other;
d) populating the second relational database with the person's name, said first identification number and said set of personal information associated with said person; and
e) communicating to said first relational database that said second relational database has been populated with the set of personal information of said person.

21. The method in accordance with claim 20, wherein the information contains personal medical data associated with the person, said personal medical data only maintained in said second server.

22. The method in accordance with claim 21, further comprising the step of accessing said personal medical data with a secure means in communication with said first server and said first software relational database.

23. The method in accordance with claim 21, further comprising the steps of:
providing a second identification number associated with the person's name and said first identification number; and
determining said second identification number utilizing a software sub-routine.

24. The method in accordance with claim 21, comprising the step of providing a direct electronic communication with the person associated with said personal medical data with said second software relational database and said second server.

25. The method in accordance with claim 21, further comprising the step of providing a direct private electronic communication with the person associated with the personal medical data and said second software relational database and said second server.

26. The method in accordance with claim 21, further comprising the step of said second software relational database and said second server prompting the person associated with said personal medical data to update their said personal data after a pre-assigned time interval after populating said second relational database.

27. The method in accordance with claim 26, wherein said time interval is between 30 and 180 days.

28. The method in accordance with claim 23, further including the step of providing said person associated with said personal medical data said second identification number.

29. The method in accordance with claim 23, wherein said second identification number provides unsecured access to said personal medical data.

30. The method in accordance with claim 20, further comprising the step of providing a portable information storage device provided in electronic communication with said second server and said second software relational database.

31. The method in accordance with claim 30, wherein the information contains personal medical data and further comprises the step of transmitting said personal medical data from said second server and said software relational database to said portable information storage device.

32. The method in accordance with claim 21, further including the step of the person associated with said personal medical data providing disclosure of said personal medical data to a legal person as a condition precedent of a contractual relationship between the person associated with the personal medical data and the legal person.
